(19) United States
(12) Patent Application Publication
(10) Pub. No.: US 2008/0285368 A1
(43) Pub. Date: Nov. 20, 2008

(54) METHOD FOR NROM ARRAY WORD LINE RETRY ERASING AND THRESHOLD VOLTAGE RECOVERING

(75) Inventors: Chun Hsiung Hung, Hsinchu (TW); Yi-Chun Shih, Hsinchu (TW)

Correspondence Address: STOUT, UXA, BUYAN & MULLINS LLP, 4 VENTURE, SUITE 300, IRVINE, CA, 92618, US

(73) Assignee: Macronix International Co., Ltd.

(21) Appl. No.: 11/750,296

(22) Filed: May 17, 2007

(51) Int. Cl. G11C 7/00

(52) U.S. Cl. 365/218

(57) ABSTRACT

A method for erasing and recovering a memory array is disclosed. The memory array includes a plurality of sectors of memory cells. After erasing a sector of the memory array, all of the memory cells of the memory array are checked to find programmed memory cells in the other un-erased sectors of the memory array. If a programmed memory cell is found, the programmed memory cell will be programmed and verified until the threshold voltage of the programmed memory cell reaches a program verify voltage.

### BACKGROUND OF THE INVENTION

1. Field of the Invention

The present invention relates generally to a semiconductor memory array, and more particularly, to a method for a word line retry erase operation and a threshold voltage recovery operation after the erase operation for a nitride read only memory (NROM) array.

2. Description of the Related Art

Nitride read only memory (NROM) cells are widely used in semiconductor industry. As is well known in the art, a typical NROM cell includes a source terminal, a drain terminal, and a gate terminal. NROM cells are generally arranged in the form of an array structure having a multiplicity of columns and a multiplicity of rows. The gate terminals of the NROM cells in the same row of an NROM array are coupled together to form a word line for this row, while the drain terminals of the NROM cells in the same column of an NROM array are coupled together to form a bit line for this column.

The NROM cells of an NROM array can be electrically programmed, read, and erased. Due to the large number of NROM cells in an NROM array, the NROM cells are generally divided into multiple sectors. A single NROM cell in an NROM array can be electrically programmed and read, whereas a sector of NROM cells can be electrically erased at the same time.

An NROM cell of an NROM array is typically programmed by establishing a large positive voltage between the gate terminal and the source terminal of the NROM cell, such as 12V, and a positive voltage between the drain terminal and the source terminal of the NROM cell, such as 6V, thus causing charges to become trapped in a retention layer of the NROM cell. The trapped charges in the retention layer of an NROM cell induce the increase of the threshold voltage for the NROM cell.

In order to verify whether the increased threshold voltage of the programmed NROM cell has reached its target programming voltage, a verifying pulse, typically following the programming pulse, is applied to the programmed NROM cell. If the verifying pulse reveals that the programmed NROM cell has not yet reached the target programming voltage, an additional programming pulse is applied, followed by a subsequent verifying pulse. Typically, during the programming process, the programming pulse increases in voltage levels, commencing at a relatively low voltage level and terminating at a higher voltage level. The programming and the verifying will continue until the target programming voltage has been reached.

The act of erasing a sector of NROM cells of an NROM array can be accomplished by applying a high positive voltage and a negative voltage to the drain terminals and the gate terminals of the NROM cells of an erase sector, respectively. However, this erase method presents a major drawback: if multiple number of sectors are divided in one physical array, the erase operation for one sector of NROM cells in an NROM array will affect programmed NROM cells belonging to other sectors in the same NROM array. Because the drain terminals of all of the NROM cells of a column in an NROM array are coupled together, during the erase operation for one sector of NROM cells, the high positive voltage applied to the drain terminals of the NROM cells belonging to the erase sector of the NROM array will also be applied to the drain terminals of the NROM cells belonging to other sectors that are not to be erased. Thus, the NROM cells of other un-erased sectors of the NROM array have to endure the column stress caused by the unnecessary high drain voltage. The column stress will result in the threshold voltage loss for the programmed NROM cells in these un-erased sectors. Although the threshold voltage loss for the programmed NROM cells caused by the column stress after one erase operation is minor, the accumulated threshold voltage loss after multiple erase operations could be significant enough such that the programmed NROM cells are mistakenly recognized to be in the erase state. This disturbance sets a limitation on the number of sectors in one array, and/or the maximum cycling number of each sector.

In view of the foregoing, there is a need for a method that is capable of performing an erase operation for one sector of an NROM array, and recovering the threshold voltage loss of the programmed NROM cells in the other sectors of the NROM array after the erase operation.

### SUMMARY OF THE INVENTION

Broadly speaking, the present invention fills this need by providing a method for erasing a sector of a memory array and then recovering threshold voltage loss of programmed memory cells in the other un-erased sectors of the memory array.

In accordance with one aspect of the present invention, a method for erasing and recovering a memory array is provided. The memory array includes a plurality of sectors of memory cells. After selecting and erasing a sector of the memory array, a threshold voltage recovery is performed for the memory array. During the threshold voltage recovery, programmed memory cells of the memory array are detected by reading the threshold voltages of all of the memory cells of the memory array. If the threshold voltage of a memory cell of the memory array reaches a program test voltage, the memory cell is considered a programmed memory cell. Thereafter, the detected programmed memory cells of the memory array are programmed and verified to make sure the threshold voltages of the programmed memory cells reaches the program verify voltage.

In accordance with another aspect of the present invention, another method for erasing and recovering a nitride read only memory (NROM) array is provided. The NROM array includes a plurality of sectors of NROM cells, each sector includes a plurality of word lines with each word line corresponding to a word line erase flag.

After a sector of the NROM array is selected for erasing, a word line of the selected sector is identified if the corresponding word line erase flag is singled. An erase verify is performed for the NROM cells coupled to the identified word line. If any of the NROM cells coupled to the identified word line fails the erase verify, the corresponding word line erase flag is flagged. After the selected sector is erased verified, an erase operation will be performed for the NROM cells coupled to the flagged word lines. The erase verification and erase operation will continue until all of the NROM cells of the selected sector pass the erase verify.

Thereafter, a threshold voltage recovery is performed for all of the sectors of the NROM array. During the threshold voltage recovery, all of the NROM cells of the NROM array are checked to see whether any programmed NROM cells exist. The programmed NROM cells are detected by reading the threshold voltages of the NROM cells. If the threshold voltage of a NROM cell reaches or goes beyond a program test voltage, the NROM cell is considered a programmed NROM cell. The detected programmed NROM cells of the NROM array are programmed again until the threshold voltages of the programmed NROM cells are greater than or equal to a program verify voltage.

In accordance with a further aspect of the present invention, a computer program embodied in a computer readable medium for erasing and recovering a memory array is provided. The memory array includes a plurality of sectors of memory cells. The computer program comprises program instructions for selecting a sector of the memory array to be erased, program instructions for erasing the memory cells of the selected sector, and program instructions for performing threshold voltage recovery for the memory array.

The program instructions for performing threshold voltage recovery for the memory array further comprises program instructions for detecting programmed memory cells of the memory array, program instructions for programming the programmed memory cells until the programmed memory cells pass a program verify.

Although specific reference is made to NROM memory cells, the methods of the claimed invention are equally applicable to other types of memory cells, which may benefit from the program verify operations after an erase operation.

It is to be understood that the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1 shows a system for erasing a nitride read only memory (NROM) array in accordance with one embodiment of the present invention.

FIG. 2 is a flow chart showing the steps of an exemplary NROM array erasing and recovering method in accordance with one embodiment of the present invention.

FIG. 3 is a flow chart showing the steps of an exemplary NROM array threshold voltage recovery method after an erasing operation in accordance with one embodiment of the present invention.

### DETAILED DESCRIPTION OF THE EXEMPLARY EMBODIMENTS

Reference is made in detail to embodiments of the invention. While the invention is described in conjunction with the embodiments, the invention is not intended to be limited by these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, as is obvious to one ordinarily skilled in the art, the invention may be practiced without these specific details. In other instances, well-known methods, procedures, components, and circuits have not been described in detail so that aspects of the invention will not be obscured.

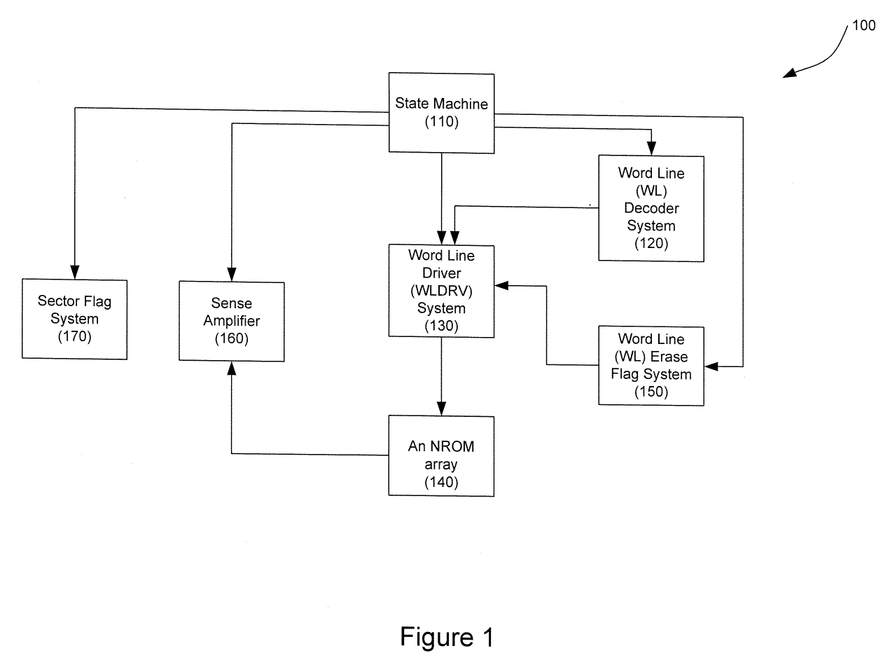

Referring initially to FIG. 1, a system 100 for erasing a nitride read only memory (NROM) array is shown in accordance with one embodiment of the present invention.

As illustrated in FIG. 1, the system 100 includes a state machine 110, a word line (WL) decoder system 120, a word line driver (WLDRV) system 130, an NROM array 140, a WL erase flag system 150, a sense amplifier 160, and sector flag system 170. The state machine 110 provides logic control to the WL decoder system 120, the WL erase flag system 150, the sense amplifier 160, and the sector flag system 170. The sector flag system 170 is configured such that for each sector of the NROM array 140, there is a corresponding sector flag that is used to indicate whether the sector of the NROM array 140 needs to be erased. The WL decoder system 120 is capable of single or multiple word line selection during an erase operation for a sector of the NROM array 140.

The sense amplifier 160 is implemented to amplify and measure the threshold voltage of an NROM cell of the NROM array 140. One approach to obtain the threshold voltage of an NROM cell of the NROM array 140 is to apply a voltage to the word line (gate terminal) of the NROM cell to be measured and compare the output current of the NROM cell with the one generated by the reference cell inside the sense amplifier 160. When the output current of the NROM cell is equal to the one of the reference cell, the voltage applied to the word line of the NROM cell is defined to be the threshold voltage of the NROM cell.

The NROM array 140 comprises a plurality of sectors of NROM cells that are arranged in multiple rows and columns. One sector can be identified as a physically isolated NROM cell array, or electrically isolated blocks of cells in one array. Each sector of the NROM array 140 includes a plurality of word lines with each word line coupled to gate terminals of NROM cells of each row. All of the drain terminals of the NROM cells of each column of the NROM array 140 are coupled together to form a bit line. Thus, different sectors of the NROM cells of the NROM array 140 share the same bit line if the NROM cells of the different sectors belonging to the same column.

The WLDRV system 130 and the WL erase flag system 150 are configured such that for each word line of the NROM array 140, there is a corresponding WLDRV and a corresponding WL erase flag. Each corresponding WLDRV includes a latch that functions as a WLDRV flag. A set WL erase flag indicates that the NROM cells coupled to the word line that corresponds to the set WL erase flag need to be erased. A reset WL erase flag indicates that the NROM cells coupled to the corresponding word line have been successfully erased, or not instructed to be erased.

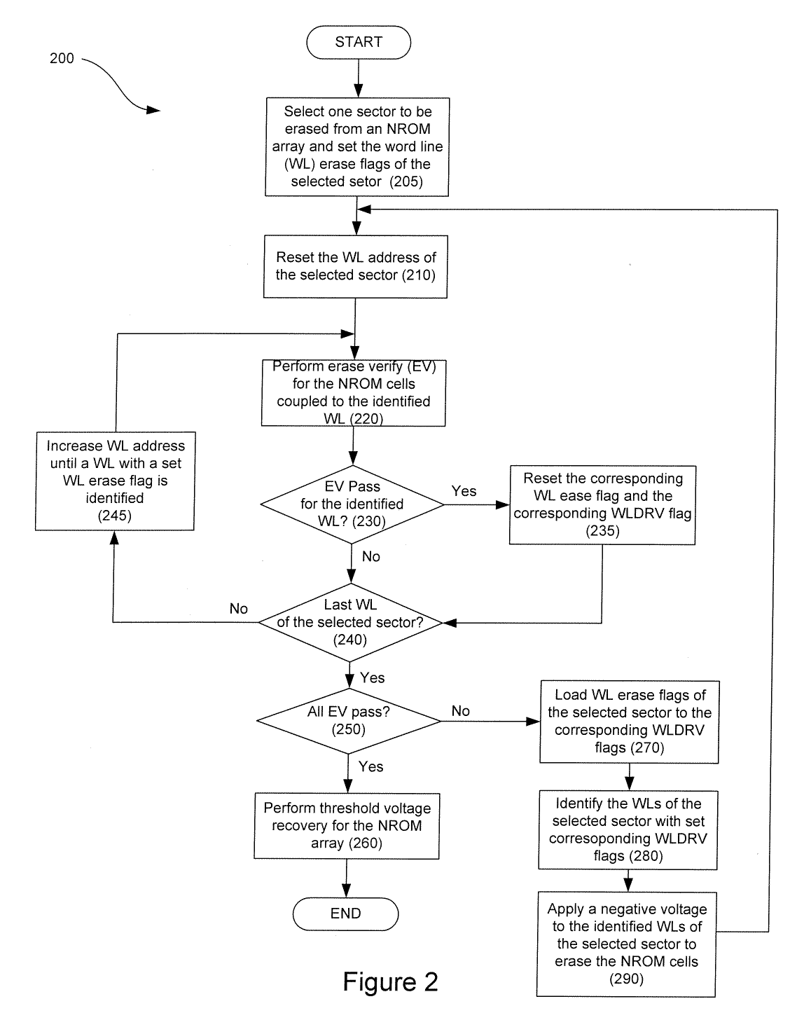

Referring now to FIG. 2, a flow chart 200 is shown to illustrate an exemplary NROM array erasing and recovering method in accordance with one embodiment of the present invention.

In step 205, a sector to be erased is selected from the plurality of sectors of the NROM array 140. Since each word line of the NROM array 140 has a corresponding WL erase flag in the WL erase flag system 150, the WL erase flags of the selected sector are set before the erase operation. The WL address of the selected sector is reset in step 210.

Next, an erase verify is performed for the NROM cells coupled to an identified word line in step 220. The erase verify can be carried out by reading the threshold voltage of each NROM cell coupled to the identified word line. The reading of the threshold voltage of an NROM cell can be implemented by applying an erase verify voltage to the identified word line to which the NROM cell to be read is coupled. If the threshold voltage of an NROM cell is less than or equal to the erase verify voltage, the NROM cell is considered to be erased. In one embodiment, the erase verify voltage used for an erase verify is about 3.0V˜3.8V.

As shown in step 230, if each NROM cell coupled to the identified word line passes the erase verify, the corresponding WL erase flag and the corresponding WLDRV flag are reset in step 235. Otherwise, the method proceeds to step 240 where the identified word line is checked to see whether it is the last word line of the selected sector. If the identified word line is not the last word line of the selected sector, the word line address of the selected sector is increased in step 245 until a word line with a set WL erase flag is identified. In case of the last word line of the selected sector, in step 250, all of the WL erase flags of the selected sector are checked to see whether all of the NROM cells belonging to the selected sector are erased.

If all of the WL erase flags of the selected sector are reset, all of the NROM cells of the selected sector are successfully erased. If at least one of the WL erase flags is still set, the values stored at the WL erase flags of the selected sector are loaded into the corresponding WLDRV flags of the selected sector in step 270. Then, in step 280, the WL decoder system 120 will identify the word lines with set corresponding WLDRV flags for the selected sector. In step 290, a negative voltage will be applied to the word lines identified in step 280 to erase the NROM cells coupled to the identified word lines. During the erase operation, the drain terminals of the NROM cells to be erased are applied with a high positive erase voltage, and the source terminals of the NROM cells to be erased are floating.

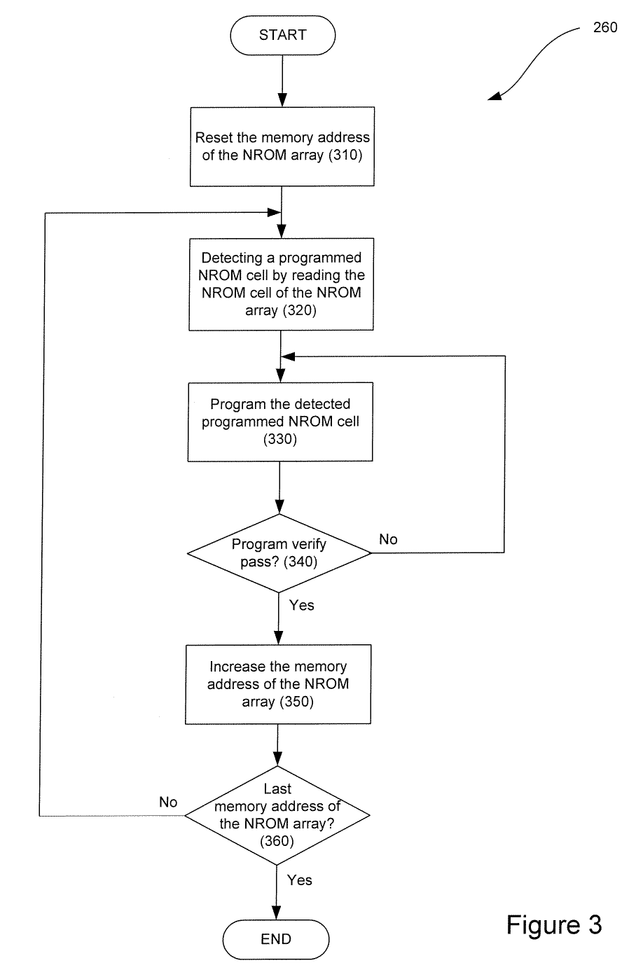

After all of the NROM cells belonging to the selected sector are erased, a threshold voltage recovery is performed for all the sectors of the NROM array 140 in step 260. The detailed execution steps of the threshold voltage recovery are illustrated in FIG. 3.

Referring now to FIG. 3, an exemplary NROM array threshold voltage recovery method after an erasing operation is shown in accordance with one embodiment of the present invention. As mentioned above, when one sector of the NROM array 140 is erased, a high positive voltage is applied to the drain terminals of the NROM cells of the sector to be erased. Because the NROM cells of each column of the NROM array 140 are coupled together, the drain terminals of the NROM cells belonging to other un-erased sectors of the NROM array 140 are also affected by the high positive voltage, which is called “column stress”. The column stress will cause losses for the threshold voltages of the programmed NROM cells in the NROM array 140. In order to maintain the threshold voltages of the programmed NROM cells in the un-erased sectors of the NROM array 140, the threshold voltage recovery needs to be performed for all of the sectors of the NROM array 140.

In step 310, the memory address of the NROM array 140 is reset. Next, a programmed NROM cell of the NROM array 140 is detected in step 320 by reading the threshold voltage of the NROM cell. As mentioned above, due to the column stress, the threshold voltage of a previously programmed NROM cell might be reduced. If the threshold voltage of an NROM cell is greater than or equal to a program test voltage, the NROM cell is detected to be a programmed NROM cell. In one embodiment, the program test voltage is about 4.0V˜4.6V.

The detected programmed NROM cell is programmed in step 330 to recover the threshold voltage loss. In step 340, the threshold voltage of the re-programmed NROM cell is verified by reading the NROM cell with a program verify voltage applied to the corresponding word line. If the threshold voltage of the programmed NROM cell does not reach the program verify voltage, another program operation is performed for the programmed NROM cell until the threshold voltage of the programmed NROM cell is greater than or equal to the program verify voltage. IN one embodiment, the program verify voltage is about 5.0V˜6.0V.

After the threshold voltage of a detected programmed NROM cell reaches or goes beyond the program verify voltage, the memory address of the NROM array is increased in step 350. The increased memory address is checked to see whether the increased memory address is the last memory address of the NROM array 140 in step 360. If the memory address is the last address of the NROM array 140, the threshold voltage recovery method is completed; otherwise, the method will continue starting from step 320.

The present invention uses word line ease flags to indicate the erase status of the memory cells coupled to the corresponding word lines, and erases a sector of a memory array by using the word line retry method. Thus, only the memory cells that failed the previous erase operation will be erased again during the subsequent erase operation. Thereafter, the memory array will undergo a threshold voltage recovery to recover the threshold voltage loss for the programmed memory cells in the un-erased sectors of the memory array. The present invention will enhance the erase speed for a memory array without degrading data retention.

NROM cells are usually formed in virtual ground arrays, where the drain and source of NROM cells are not distinguished. The localized nature of charge trapping in a nitride layer of an NROM cell makes it capable of storing two bits per cell. Although common drain NROM arrays are described for the above-mentioned embodiments, this invention also applies to common source NROM arrays or virtual ground arrays.

The foregoing descriptions of specific embodiments of the invention have been presented for purposes of illustration and description. They are not intended to be exhaustive or to limit the invention to the precise forms disclosed. Obviously, many modifications and variations are possible in light of the above teaching. The embodiments were chosen and described in order to explain the principles and the application of the invention, thereby enabling others skilled in the art to utilize the invention in its various embodiments and modification s according to the particular purpose contemplated. The scope of the invention is intended to be defined by the claims appended hereto and their equivalents.

What is claimed is:

1. A method for erasing and recovering a memory array, the memory array including a plurality of sectors of memory cells, the method comprising:
selecting a sector of the memory array to be erased;
erasing memory cells of the selected sector of the memory array; and
performing threshold voltage recovery for cells of the memory array which are not in the selected sector of the memory array.

2. The method for erasing and recovering a memory array as recited in claim 1, wherein the performing of the threshold voltage recovery further comprises:
detecting a programmed memory cell from the memory array;
programming the programmed memory cell until the programmed memory cell passes program verify; and
repeating the detecting and the programming until all programmed memory cells of the memory array pass the program verify.

3. The method for erasing and recovering a memory array as recited in claim 2, wherein the detecting of the programmed memory cell further comprises:
reading threshold voltage of a memory cell of the memory array; and
identifying the memory cell to be the programmed memory cell if the threshold voltage of the memory cell is greater than or equal to a program test voltage.

4. The method for erasing and recovering a memory array as recited in claim 1, wherein the memory cells are NROM cells.

5. The method for erasing and recovering a memory array as recited in claim 1, wherein the erasing of the memory cells of the selected sector of the memory array further comprises:
identifying a word line that is flagged from a plurality of word lines of the selected sector;
performing erase verify for memory cells coupled to the identified word line;
flagging the identified word line if the erase verify fails;
repeating the identifying, the performing, and the flagging until last word line of the selected sector;
erasing memory cells coupled to flagged word lines; and
iterating the identifying, the performing, the flagging, the repeating, and the erasing until all memory cells of the selected sector pass the erase verify.

6. The method for erasing and recovering a memory array as recited in claim 5, wherein the flagging of the identified word line is accomplished by setting a word line erase flag that corresponds with the identified word line.

7. The method for erasing and recovering a memory array as recited in claim 5, wherein the erasing of the memory cells of the selected sector of the memory array further comprises:
setting a plurality of word line erase flags that corresponds to the plurality of word lines of the selected sector before the identifying of the word line.

8. A method for erasing and recovering a memory array that includes a plurality of sectors of the memory cells, each sector including a plurality of word lines, each word line having a corresponding word line erase flag, the method comprising:
selecting a sector from the plurality of sectors of the memory array to be erased;
identifying a word line that is flagged from the plurality of word lines of the selected sector;
performing erase verify for memory cells coupled to the identified word line;
flagging the identified word line if the erase verify fails;
repeating the identifying, the performing, and the flagging until last word line of the selected sector;
erasing memory cells coupled to flagged word lines;
iterating the identifying, the performing, the flagging, the repeating, and the erasing until all memory cells of the selected sector pass the erase verify; and
performing threshold voltage recovery for all sectors of the memory array.

9. The method for erasing and recovering a memory array as recited in claim 8, wherein the performing of the threshold voltage recovery further comprises:
detecting a programmed memory cell from the selected sector of the memory array; and
programming the programmed memory cell until the programmed memory cell passes program verify; and
repeating the detecting and the programming until all programmed memory cells of the selected sector of the memory array pass the program verify.

10. The method for erasing and recovering a memory array as recited in claim 9, wherein the detecting of the programmed memory cell is performed by
reading threshold voltage of a memory cell of the selected sector of the memory array; and
identifying the memory cell to be the programmed memory cell if the threshold voltage of the memory cell is greater than or equal to a program test voltage.

11. The method for erasing and recovering a memory array as recited in claim 10, wherein the memory array is an NROM array.

12. The method for erasing and recovering a memory array as recited in claim 11, wherein the program test voltage is about 4.0V˜4.6V.

13. The method for erasing and recovering a memory array as recited in claim 11, wherein the programmed memory cell passes the program verify if threshold voltage of the programmed memory cell is greater than or equal to 5.0V˜6.0V.

14. The method for erasing and recovering a memory array as recited in claim 11, wherein the memory cells coupled to the identified word line pass the erase verify if each threshold voltage of each memory cell coupled to the identified word line is less than or equal to 3.0V˜3.8V.

15. The method for erasing and recovering a memory array as recited in claim 11, wherein the identifying of the word line from the plurality of word lines of the selected sector is performed by choosing a word line whose corresponding word line erase flag is flagged.

16. The method for erasing and recovering a memory array as recited in claim 11, wherein the erasing of the memory cells coupled to the identified word line is performed by applying a negative voltage to the identified word line.

17. A computer program embodied in a computer readable medium for erasing and recovering a memory array that includes a plurality of sectors, comprising:
program instructions for selecting a sector from the plurality of sectors of the memory array to be erased;
program instructions for erasing memory cells of the selected sector; and
program instructions for performing threshold voltage recovery for cells of the memory array which are not in the selected sector of the memory array.

18. The computer program embodied in a computer readable medium for erasing and recovering a memory array as recited in claim 17, wherein the program instructions for performing the threshold voltage recovery further comprises:
program instructions for detecting a programmed memory cell from the memory array;
program instructions for programming the programmed memory cell until the programmed memory cell passes program verify; and
program instructions for repeating the detecting and the programming until all programmed memory cells of the memory array pass the program verify.

19. The computer program embodied in a computer readable medium for erasing and recovering a memory array as recited in claim 18, wherein the program instructions for detecting of the programmed memory cell further comprising:
program instructions for reading threshold voltage of a memory cell of the memory array; and
program instructions for identifying the memory cell to be the programmed memory cell if threshold voltage of the memory cell is greater than or equal to a program test voltage.

20. The computer program embodied in a computer readable medium for erasing and recovering a memory array as recited in claim 17, wherein the memory cells are NROM cells.

21. The computer program embodied in a computer readable medium for erasing and recovering a memory array as recited in claim 17, wherein the program instructions for erasing the memory cells of the selected sector of the memory array further comprises:
program instructions for identifying a word line that is flagged from a plurality of word lines of the selected sector;
program instructions for performing erase verify for memory cells coupled to the identified word line;
program instructions for flagging the identified word line if the erase verify fails;
program instructions for erasing the memory cells coupled to the identified word line if the erase verify fails;
program instructions for repeating the identifying, the performing, and the flagging until last word line of the selected sector;
program instructions for erasing memory cells coupled to flagged word lines; and
program instructions for iterating the identifying, the performing, the flagging, the repeating, and the erasing until all memory cells of the selected sector pass the erase verify.

22. The computer program embodied in a computer readable medium for erasing and recovering a memory array as recited in claim 21, wherein the identifying of the word line is performed by choosing a word line from the plurality of word lines of the selected sector of the memory array if corresponding word line erase flag is flagged.
